(19) United States
(12) Patent Application Publication
(10) Pub. No.: US 2008/0160263 A1
(43) Pub. Date: Jul. 3, 2008

(54) Fabrication Of Front Filter For Plasma Display Panel

(76) Inventors: Kyoo Choong Cho, Chungcheongnam-do (KR); Chan Hong Park, Seoul (KR); Byong Kook Park, Gyeonggi-do (KR)

Correspondence Address: FROMMER LAWRENCE & HAUG, 745 FIFTH AVENUE- 10TH FL., NEW YORK, NY, 10151, US

(21) Appl. No.: 11/914,820

(22) PCT Filed: May 24, 2006
(86) PCT No.: PCT/KR06/01953

§ 371 Date: Nov. 19, 2007

(30) Foreign Application Priority Data
Jun. 1, 2005 (KR) 10-2005-0046834

(51) Int. Cl. G02B 5/20; G02B 1/11; H05K 9/00

(52) U.S. Cl. 428/203

(57) ABSTRACT

The present invention relates to a method for fabricating a front filter for a plasma display panel (PDP). In particular, the present invention relates to a front filter for a PDP comprising functional films including a conductive mesh film (2) having a black treated layer (2a), an optical film (1c) and an antireflection film (4) laminated on a glass substrate (3), wherein a transparent glass substrate (3) is used without a black ceramic stripe, which is formed at the rear side of the glass substrate (3) to improve visibility. Instead, composition and thickness of the oxide film forming the black treated layer (2a) of the conductive mesh film (2) are adjusted to attain comparable or better visibility, as compared with conventional filters. The minimized one-step fabricating process of the present invention provides advantages in terms of cost effectiveness and environment friendliness.

### TECHNICAL FIELD

The present invention relates to a method for fabricating a front filter for a plasma display panel (PDP), more particularly to a front filter for a PDP comprising functional films including a conductive mesh film having a black treated layer at least on the viewer's side, an optical film and an antireflection film laminated on a glass substrate, wherein a transparent glass substrate is used without a black ceramic stripe, which is formed at the rear side of the glass substrate to improve visibility. Further, instead, composition and thickness of the oxide film forming the black treated layer of the conductive mesh film are adjusted to attain comparable or better visibility, as compared with conventional filters. The one-step fabricating process of the present invention is advantageous in terms of cost and environment friendliness.

### BACKGROUND ART

A PDP (plasma display panel) is a flat, light-emitting display device easier to make bigger than other display devices. It is viewed as the most fitting display device for the next-generation, high-quality digital televisions. However, a PDP is disadvantageous in that the level of electromagnetic wave and near infrared ray radiation is high, the degree of surface reflection of phosphor is high and also the color purity is worse than that of a cathode ray tube because of the orange light emitted by neon filled in the PDP. Besides, a PDP is composed of 3 mm-thick upper and lower boards, and thus the panel may be easily broken by external force.

Thus, a front filter is used in order to protect people and devices from electromagnetic interference (EMI) and near infrared ray radiation, reduce surface reflection, improve color purity and protect the PDP from external force.

The front filter for a PDP is classified into one for industrial-use and one for general-use, depending on the level of EMI shielding. The industrial-use (Class A) front filter for a PDP is fabricated by coating a metal such as silver (Ag) and an oxide with a high refractive index alternately on the rear side of a substrate to form an electromagnetic wave and near infrared ray shielding layer and forming or laminating antireflection films on both sides of the glass substrate.

Further, the general-use (Class B) front filter is fabricated by attaching a conductive mesh film in which a copper (Cu) pattern is etched on a glass substrate using an adhesive or a glue, laminating an antireflection film on the surface of the glass substrate and laminating a film having a near infrared ray shielding layer on the rear side of the substrate.

Because the conductive mesh film for EMI shielding is made of metal, external light is reflected at the film, which impairs visibility and contrast of the display. In order to prevent this, the conductive mesh film is oxidized or black treated with black organic materials at the viewer side.

For the glass substrate used in the front filter of a PDP, semi-tempered glass or tempered glass having a breaking strength 2-5 times larger than general floating glass (soda lime glass) is used to improve impact resistance. In addition, a black ceramic stripe about 3 cm wide is formed around the frame of the glass substrate by silk screen printing, in order to improve visibility. Further, the glass is R- or C-bevel treated for the safety of users.

When fabricating a conventional front filter for a class B PDP, an antireflection film is formed on the front side of a tempered glass in which a stripe is printed at the rear side, a conductive mesh film is formed at the rear side or front side of the tempered glass and films for shielding near infrared rays and improving color purity are formed at the rear side or the front side. In any case, the antireflection film has to be formed at the most front side of the tempered glass substrate.

The conventional tempered glass in which a black ceramic stripe is formed at the rear side by printing is disadvantageous in that printing of the black ceramic stripe requires a high cost and manufacturing yield of the tempered glass is not good because of such problems as pinholes during the printing. Moreover, environmentally hazardous materials are included in the black ink.

The present inventors have made extensive efforts to improve manufacturing efficiency in manufacturing process, cost effectiveness and environment friendliness in the process of black ceramic stripe formation at the rear side of a glass substrate. As a result, they discovered that a front filter for a PDP comprising a glass substrate and functional films including a conductive mesh film having a black treated layer, an optical film and an antireflection film, wherein a transparent glass substrate is used without a black ceramic stripe, which is printed along the frame of the glass substrate to improve visibility, however, instead, composition and thickness of the copper oxide film forming the black treated layer of the conductive mesh film are adjusted, offers comparable or better visibility, as compared with conventional filters, while improving cost effectiveness with minimal, one-step process and environment-friendliness.

Accordingly, it is an object of the present invention to provide a method for fabricating a front filter for a PDP, which offers comparable or better visibility, as compared with conventional filters, with a simplified process.

### DISCLOSURE

The present invention relates to a front filter for a PDP comprising functional films including a conductive mesh film having a black treated layer at least on the viewer's side, an optical film and an antireflection film laminated on a glass substrate, wherein a transparent glass substrate is used without a black ceramic stripe, which is formed at the rear side of the glass substrate to improve visibility, but, instead, a copper oxide film comprising CuO and Cu₂O with a molar ratio of 1:0.1-1 is laminated to a thickness of 0.01-1 μm to form the black treated layer of the conductive mesh film.

Hereunder is given a more detailed description of the present invention.

The present invention relates to a front filter for a PDP comprising functional films including a conductive mesh film having a black treated layer at least on the viewer's side, which is formed from a copper oxide film, an optical film and an antireflection film laminated on a transparent glass substrate, which offers comparable or better visibility, as compared with conventional filters, while improving economy with minimal, one-step process and environment friendliness.

Visibility, or the degree of something to be seen and perceived, is an important factor for a PDP. Conventionally, in the front filter for a PDP, there is usually formed a black ceramic stripe along the frame of a glass substrate and a black treated layer is formed on the surface of a conductive mesh film for EMI shielding in order to improve visibility. However, because the printing process for forming the black ceramic stripe is not an easy process, it results in significant increase in production cost as compared with a transparent glass substrate. Besides, the ink used to form the black ceramic stripe, being an environmentally hazardous material, is under strict regulation. The main purpose of the conductive mesh film is to shield EMI, but improvement in visibility to some extent is expected by the blackening treatment. The blackening is performed by coating the conductive film with oxides and organic materials.

The technical feature of the present invention is that a transparent substrate is used to reduce manufacturing cost and improve visibility is attained by forming a specially designed black treated layer on the conductive mesh film. The present invention is advantageous in that it provides comparable or better visibility as compared with conventional filters, while improving cost effectiveness with minimal, one-step process and environment friendliness.

The film for forming the black treated layer is prepared from a copper oxide with a specific molar ratio to a specific thickness. The copper oxide film comprises CuO and Cu₂O with a molar ratio of 1:0.1-1, preferably 1:0.1-0.5, and is formed to a thickness of 0.01-1 μm. The composition of the copper oxide is determined by the degree of oxidation, which can be controlled by the methods well known in the art.

If the proportion of Cu₂O is less than 0.1 mole per 1 mole of CuO, the capacity of EMI shielding decreases because of small electric conductivity. In contrast, if it exceeds 1 mole, the degree of blackening decreases. Further, if the copper oxide film is thinner than 0.01 μm, the degree of blackening decreases. In contrast, if it is thicker than 1 μm, the film is easily broken to form powders.

The resultant conductive mesh film offers the same effect as those prepared by several steps according to the conventional method, with improved degree of blackening adjustable with the composition and thickness of the film.

Now, the front filter for a PDP of the present invention is described in further detail, referring to FIG. 1.

For the substrate (3) of the front filter, transparent glass, more particularly floating (soda lime) glass, without a black ceramic stripe printed around the frame is used. Beveled, corner-cut or tempered glass may be used, too. The glass substrate has to be light and have good impact resistance. It is recommended that the glass substrate has a thickness of 2-4 mm, preferably 2.5-3 mm, for preventing wave distortion.

Typically, functional films including a conductive mesh film for EMI shielding, an optical film for shielding near infrared ray s and neon light and an antireflection film are laminated on the glass substrate.

On one side of the glass substrate (see FIG. 2), a mesh (2e) is formed by patterning with copper on a transparent plastic film (2c) made of, for example, polyester. The glass substrate has a copper frame (2f) without pattering for grounding. On the film side of the copper mesh, which is being black treated for visibility improvement, an adhesive layer (2d) is formed for adhesion with the glass substrate. The margin between the edge of the glass and the grounding surface of the mesh film is within ±2 mm, more preferably within ±1 mm.

As a film for shielding near infrared rays and neon light radiated from the PDP and thereby improving color purity, a layer (1b) including a pigment for shielding near infrared rays and a pigment for selectively absorbing light is formed on a transparent thermoplastic resin substrate film (1a).

The transparent thermoplastic resin substrate film may be any one commonly used in the art. Specifically, thermoplastic resins such as polyethylene terephthalate (PET), polycarbonate (PC), polymethyl methacrylate (P mm A), triacetate cellulose (TAC) and polyethersulfone (PES) may be used. It is recommended that the substrate film has a thickness of 25-250 μm and a transmittance of at least 80%, more preferably at least 90%.

The layer (1b) is formed by coating a solution containing a pigment for shielding near infrared rays and a pigment for selectively absorbing light on a transparent thermoplastic substrate film. The pigment for shielding near infrared rays may be any one commonly used in the art and is not particularly limited. However, a composite pigment of nickel complex and diammonium, a compound pigment including copper or zinc ion, an organic pigment, etc. are preferable. More preferably, the pigment for shielding near infrared rays is used within 1.0-20 parts by weight per 100 parts by weight of the total solid content.

The pigment for selectively absorbing light may be any one commonly used in the art. Preferably, a derivative pigment presented by Korean Patent Publication Nos. 2001-026838 and 2001-039727, in which a metal atom (M) present in tetraazaporphyrin is coordinated by a ligand selected from ammonia, water and halogen, is used. Preferably, the metal (M) may be selected from a group consisting of zinc (Zn), palladium (Pd), magnesium (Mg), manganese (Mn), cobalt (Co), copper (Cu), ruthenium (Ru), rhodium (Rh), iron (Fe), nickel (Ni), vanadium (V), tin (Sn) and titanium (Ti). The pigment for selectively absorbing light is used within 0.01-5.0 parts by weight per 100 parts by weight of the total solid content. If the content of the pigment is less than 0.01 part by weight, improvement of color purity cannot be expected because the capacity of selective light absorption declines. In contrast, if it exceeds 5.0 parts by weight, color balance of the filter is distorted and transmittance decreases.

In addition to the pigment for shielding near infrared rays and the pigment for selectively absorbing light, an azo dye, a cyanine dye, a diphenylmethane dye, a triphenylmethane dye, a phthalocyanine dye, a xanthene dye, a diphenylene dye, an indigo dye, a porphyrin dye, etc. may be added for wavelength-specific transmittance control or whiteness improvement. Preferably, the dyes are used within about 0.05-3 wt % per 100 wt % of the total solid content. If the content of the dyes is below 0.05 wt %, no advantage is attained by their addition. Further, if the content exceeds 3 wt %, relative content of other compounds decreases.

The pigments are mixed with a transparent plastic binder and a solvent to prepare a solvent that is coated on the transparent thermoplastic film. The transparent plastic binder may be a transparent plastic resin, for example, poly(methyl methacrylate) (PMMA), polyvinyl alcohol (PVA), polycarbonate (PC), ethylene vinyl acetate (EVA), poly (vinylbutyral) (PVB) and polyethylene terephthalate (PET). Preferably, the transparent plastic binder is used within 5-40 wt % per 100 wt % of the solvent.

For the solvent used in the pigment-containing coating composition, one commonly used in the art may be used. For example, toluene, xylene, acetone, methyl ethyl ketone (MEK), propyl alcohol, isopropyl alcohol, methyl cellosolve, ethyl cellosolve or dimethylformamide (DMF) may be used.

Several stabilizers may be further added to the coating composition in order to improve light stability. Typically, such a stabilizer as a radical reaction inhibitor for preventing discoloration of pigments is used within 15-50 parts by weight per 100 parts by weight of the total solid content.

The coating may be performed by any method commonly used in the art and is not particularly limited in the present invention. For example, roll coating, die coating or spin coating may be performed. Preferably, the coating is performed so that the post-drying thickness becomes about 1-20 μm, more preferably about 2-10 μm, for better near infrared ray shielding.

The conductive mesh (2a) may be a conductive fiber mesh using metal fiber or metal-coated fiber or a patterned metal mesh formed by photolithography or screen printing. The conductive mesh is formed on the transparent thermoplastic substrate film (2c), which is laminated on the glass substrate by the transparent adhesive (2d). The present invention is characterized in that at least the frame of the substrate film or the metal mesh is coated by a copper oxide with a specific composition and thickness for visibility improvement.

The black ceramic stripe may be formed by any method commonly used in the art and is not particularly limited. In an embodiment of the present invention, a copper film is oxidized to form a black treated layer and is attached to the transparent thermoplastic film, which is etched and patterned by photolithography to obtain a mesh film.

It is recommended that the conductive mesh film has a line pitch of 50-500 μm, preferably 100-400 μm, and a line width of 1-100 μm, preferably 5-50 μm. If the pitch of the mesh is smaller, transmittance becomes decreased. In contrast, if it is larger, EMI shielding capacity decreases.

The resultant thermoplastic resin film (1), on which the layer (1b) for near infrared ray shielding and selective light absorption has been coated, is laminated on the glass substrate (3), on which the conductive mesh film (2) has been laminated, using a transparent adhesive. The lamination can be performed by any method commonly used in the art. For example, roll lamination, sheet lamination, etc. may be used. Roll lamination is preferred for better productivity.

Typically, a transparent acrylic adhesive is used for the transparent adhesive used in the lamination of each film. A sufficient adhesion strength can be attained when the haze of the adhesive layer is 3.0 or smaller, preferably 1.0 or smaller, and the thickness of the adhesive layer is within 10-100 μm, preferably within 15-50 μm. If the adhesive layer is thinner than 10 μm, sufficient adhesion strength cannot be obtained. Further, if it is thicker than 100 μm, it results in increase in haze and rework performance becomes poor.

The adhesive layer may be formed by coating a solution comprising an adhesive, a solvent, a hardener and other additives on the film. The coating may be formed by, for example, roll coating, die coating, comma coating or lip coating. Alternatively, an adhesive layer formed on a release film in advance may be transcribed on the film for near infrared ray and neon light shielding.

Then, an antireflection film (4) is formed at the front side of the glass, on which the mesh film and the film for near infrared ray and neon light shielding have been laminated on the rear side of the glass, or on the laminate by roll lamination.

Then, the mesh is treated to make it transparent. The mesh transparency process of the present invention is as follows: (a) a patterned mesh film is laminated on the rear side of the transparent glass substrate (3) using an adhesive; (b) a film (1) capable of shielding near infrared and absorbing neon light layer is laminated on top of the metal mesh (2a) using an adhesive; and finally (c) anti-reflection film is laminated on the front side of the transparent glass substrate, that is, in the order of anti-reflection film/glass/mesh/near infrared shielding film.

The resultant filter is heated and pressurized in an autoclave. The filter is heated at 40-200° C., preferably at 50-100° C., and pressurized at 1-10 kgf/cm², preferably at 2-5 kgf/cm². Preferably, air or steam is used for the pressurization. After heating and pressurization for about 30 minutes, the filter is cooled inside the autoclave or in the air. The cooling may be performed by air cooling, water cooling or fluid cooling, but water cooling is preferred with regard to productivity.

In the transparency treatment, mesh the adhesive layer for making the mesh pattern transparent may be present either at the rear side of the plastic film having the layer for near infrared ray shielding and neon light absorption or at the rear side of the antireflection film.

A protection film may be attached at the (outermost) rear side of the film having the layer for near infrared ray shielding and neon light absorption or at the front side of the antireflection film in order to prevent scratch or contamination by impurities which may occur during the heating and pressurization in the autoclave.

The order of lamination of the functional films may be different from that shown in FIG. 1. For example, 1) a conductive mesh film having a black treated layer and an optical film may be sequentially laminated at the rear side of a transparent glass substrate and an antireflection film may be laminated at the front side of the transparent glass substrate; 2) a conductive mesh film having a black treated layer, an optical film and an antireflection film may be sequentially laminated at the front side of a transparent glass substrate; or 3) a conductive mesh film having a black treated layer, and a composite film having dual functions of optical and antireflection activities may be sequentially laminated at the front side of a transparent glass substrate. That is, the functional films may be laminated in a variety of ways without departing from the purpose of the present invention.

As described above, the front filter for a PDP according to the present invention is fabricated by sequentially laminating a conductive mesh having a specific black treated layer and a transparent thermoplastic film coated with a pigment layer, which shields near infrared rays and selectively absorbs light for improving color purity, on a transparent glass substrate without a black ceramic stripe at the frame, laminating an antireflection film at the rear side or front side and making it transparent by heating and pressurizing in an autoclave. The method for fabricating a front filter for a PDP of the present invention is advantageous in that manufacturing cost of the filter can be reduced by omitting the process of ceramic printing. In addition, the following color coordinate values can be attained: Y=1-3, x=0.17-0.27, y=0.15-0.25, ΔE=1.0 or smaller.

### DESCRIPTION OF DRAWINGS

FIG. 1 illustrates the cross-section of the front filter for a PDP fabricated in Example 1.

FIG. 2 schematically illustrates the copper-patterned conductive film for EMI shielding of Example 1.

FIG. 3 illustrates the lamination structure of the front filter for a PDP fabricated in Example 2.

FIG. 4 illustrates the lamination structure of the front filter for a PDP fabricated in Example 3.

FIG. 5 illustrates the lamination structure of the front filter for a PDP fabricated in Example 4.

FIG. 6 illustrates the lamination structure of the front filter for a PDP fabricated in Comparative Example 1.

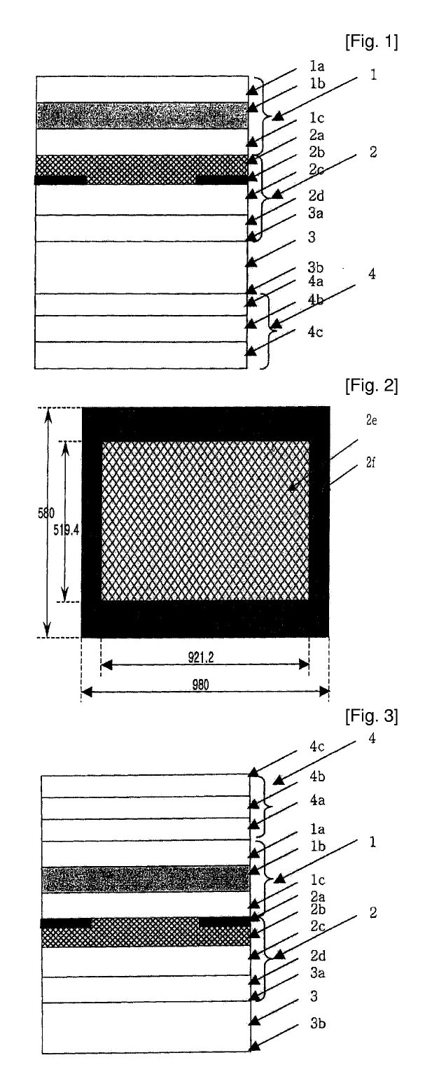

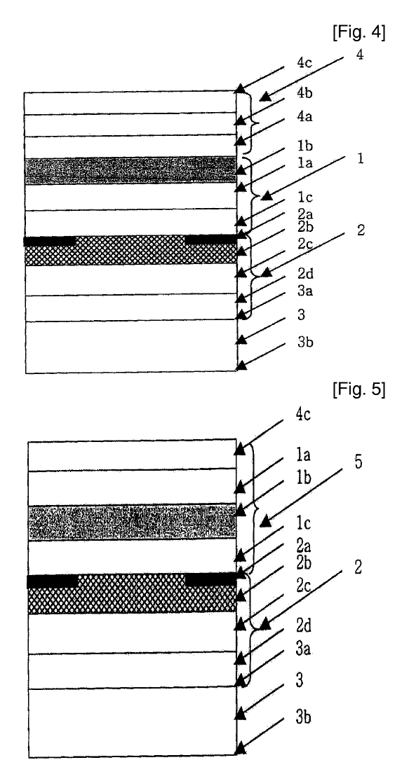

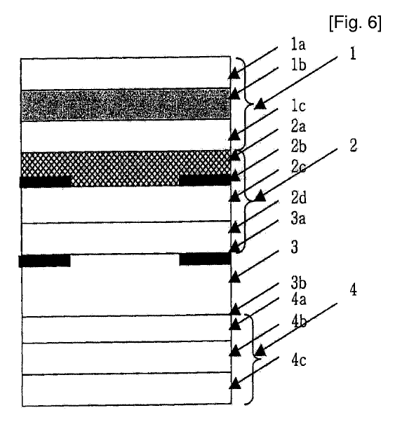

### BEST MODE

Practical and preferred embodiments of the present invention are illustrated in the following examples. However, it will be appreciated that those skilled in the art, in consideration of this disclosure, may make modifications and improvements within the spirit and scope of the present invention.

### EXAMPLE 1

(Step 1) Preparation of Beveled, Semi-Tempered Glass

2.8 mm-thick soda lime glass was cut to a size of 584×984 mm and beveled to C 0.2-1.2 mm. Then, the four comers were cut to C 5±3 mm or R 7±3 mm. The glass was tempered in a tempering furnace at about 500° C.

(Step 2) Lamination of Functional Films

On one side of the glass prepared in the step 1, a roll-shaped mesh film (see FIG. 2) having a continuous copper pattern formed on a polyester film and having an adhesive layer formed at the rear side of the polyester film, at which at least polyester film side of the copper had been black treated under alkali atmosphere for 3-4 minutes, was laminated at room temperature and under a pressure of 3 kgf/cm² using a roll laminator, at a rate of 1 m/min with a margin of 2 mm at four edges. A film for near infrared ray and neon light shielding, in which a layer for near infrared ray and neon light shielding had been formed on a polyester film and an adhesive layer had been formed on the layer, was cut to a size of 556×955 mm and laminated above the mesh film which had been laminated at the rear side of the glass at room temperature and under a pressure of 3 kgf/cm², at a rate of 1 m/min. On the front side of the laminate, an antireflection film cut to a size of 580×980 mm was laminated at room temperature and under a pressure of 3 kgf/cm² at a rate of 1 m/min.

(Step 3) Transparency Treatment

The resulting laminate was put in an autoclave and kept at 80° C. under an air pressure of 5 kgf/cm² for 60 minutes. A front filter for a PDP was obtained after cooling for about 30 minutes.

### EXAMPLE 2

The roll-shaped mesh film used in the step 2 of Example 1 having a continuous copper pattern formed on a polyester film and having an adhesive layer formed at the rear side of the polyester film, at least the film side of which had been black treated, was laminated at room temperature and under a pressure of 3 kgf/cm² using a roll laminator, at a rate of 1 m/min with a margin of 2 mm at four edges. A film for near infrared ray and neon light shielding, in which a layer for near infrared ray and neon light shielding had been formed on a polyester film and an adhesive layer had been formed on the layer, was cut to a size of 556×955 mm and laminated on the front side of the laminate at room temperature and under a pressure of 3 kgf/cm², at a rate of 1 m/min. On the front side of the laminate, an antireflection film cut to a size of 580×980 mm was laminated at room temperature and under a pressure of 3 kgf/cm² at a rate of 1 m/min. The laminate was made transparent in the same manner as in Example 1 to obtain a front filter.

### EXAMPLE 3

The roll-shaped mesh film used in the step 2 of Example 1 having a continuous copper pattern formed on a polyester film and having an adhesive layer formed at the rear side of the polyester film, at least the patterned side of which had been black treated, was laminated at room temperature and under a pressure of 3 kgf/cm² using a roll laminator, at a rate of 1 m/min with a margin of 2 mm at four edges.

A film for near infrared ray and neon light shielding, in which a layer for near infrared ray and neon light shielding had been formed on a polyester film and an adhesive layer had been formed on the layer, was cut to a size of 556×955 mm and laminated on the front side of the laminate at room temperature and under a pressure of 3 kgf/cm², at a rate of 1 m/min, in such a manner that the adhesive layer contacted the mesh surface.

On the front side of the laminate, an antireflection film cut to a size of 556×955 mm was laminated at room temperature and under a pressure of 3 kgf/cm² at a rate of 1 m/min. The laminate was made transparent in the same manner as in Example 1 to obtain a front filter.

### EXAMPLE 4

The roll-shaped mesh film used in the step 2 of Example 1 having a continuous copper pattern formed on a polyester film and having an adhesive layer formed at the rear side of the polyester film, at least the patterned side of which had been black treated, was laminated at room temperature and under a pressure of 3 kgf/cm² using a roll laminator, at a rate of 1 m/min with a margin of 2 mm at four edges. A composite film for shielding near infrared rays and neon light and preventing reflection, in which a layer for near infrared ray and neon light shielding and an adhesive layer had been formed on one side of a polyester film and an antireflection layer had been formed on the other side of the polyester film, was cut to a size of 556×955 mm and laminated on the front side of the laminate at room temperature and under a pressure of 3 kgf/cm², at a rate of 1 m/min. The laminate was made transparent in the same manner as in Example 1 to obtain a front filter.

### COMPARATIVE EXAMPLE 1

(Step 1) Preparation of Beveled, Printed, Semi-Tempered Glass

2.8 mm-thick floating glass (soda lime glass) was cut to a size of 584×984 mm and beveled to C 0.2-1.2 mm. Then, the four corners were cut to C 5±3 mm or R 7±3 mm. A black ceramic ink was silk screen printed with a width of 30 mm around the frame of the glass. After drying, the glass was tempered in a tempering furnace at about 500° C.

A front filter for a PDP was obtained in the same manner as in the steps 2 and 3 of Example 1.

### COMPARATIVE EXAMPLE 2

A front filter for a PDP was obtained in the same manner as in Example 1, except that the blackening treatment of the conductive mesh film was performed by alkali oxidation.

### TEST EXAMPLE 1

Reflection at the black treated area of the front filters was measured with an integrating sphere spectrophotometer. Colorquest XE designed by HunterLab (U.S.) and C light source were used.

The result of reflection measurement at the black treated area of the front filters fabricated in Examples 1-4 and Comparative Examples 1-2 is given in Table 1 below. In Table 1, Y is brightness and ΔE is the deviation of the filters fabricated in Comparative Example 2 and Examples 1, 2, 3 and 4 from the filter fabricated in Comparative Example 1.

TABLE 1

Reflection measurement result

| | Y | x | y | ΔE |
|---|---|---|---|---|
| Example 1 | 2.03 | 0.2385 | 0.2213 | 0.35 |
| Example 2 | 1.49 | 0.23721 | 0.1995 | 0.20 |
| Example 3 | 1.58 | 0.2351 | 0.2054 | 0.11 |
| Example 4 | 1.55 | 0.2365 | 0.2125 | 0.13 |
| Comparative | 1.685 | 0.2124 | 0.1982 | 0 |
| Example 1 | | | | |
| Comparative | 4.15 | 0.2887 | 0.2678 | 2.47 |
| Example 2 | | | | |

As seen in Table 1, the front filters fabricated in Examples 1-4 showed no difference in antireflection performance as compared with that fabricated in Comparative Example 1, in which the semi-tempered glass substrate black treated by screen printing was used.

That is, Y was in the range of from 1-3, x was in the range of from 0.17-0.27, y was in the range of from 0.15-0.25 and ΔE was 1.0 or smaller.

### TEST EXAMPLE 2

Composition and thickness of the black treated layer formed on the each conductive mesh film of Example 1 and Comparative Example 2 were measured. The result is given in Table 2 below.

TABLE 2

| | Example 1 | Comparative Example 2 |
|---|---|---|
| Composition (CuO:Cu₂O) | 1:0.1 | 1:1 |
| Thickness | 0.05 | 0.05 |

As seen in Table 2, the oxide film of the conductive mesh film of Example 1 had a composition of CuO:Cu₂O of 1:0.1 and a thickness of 0.05 μm which could offer comparable or better color coordinate and deviation, as compared with conventional films.

In contrast, the oxide film of Comparative Example 2, which was prepared under alkali atmosphere by the conventional method, had a composition which could not offer a comparable effect.

### INDUSTRIAL APPLICABILITY

As apparent from the above description, the front filter for a PDP fabricated in accordance with the present invention is advantageous in improving economy, because the process for attaining visibility is minimized, and environment friendliness.

Those skilled in the art will appreciate that the conceptions and specific embodiments disclosed in the foregoing description may be readily utilized as a basis for modifying or designing other embodiments for carrying out the purposes of the present invention. Those skilled in the art will also appreciate that such equivalent modifications do not depart from the spirit and scope of the present invention as set forth in the appended claims.

1. A front filter for a plasma display panel comprising functional films including a conductive mesh film having a black treated layer, an optical film and an antireflection film laminated on a glass substrate,
wherein the glass plate is a transparent glass substrate without a black ceramic stripe; and the black treated layer of the conductive mesh film is formed by lamination of a copper oxide film comprising CuO and Cu₂O with a molar ratio of 1:0.1-1 to a thickness of 0.01-1 μm.

2. The front filter for a plasma display panel as set forth in claim 1, wherein a conductive mesh film having a black treated layer and an optical film are sequentially laminated on the rear side of the transparent glass substrate, and an antireflection film is laminated on the front side of the transparent glass substrate.

3. The front filter for a plasma display panel as set forth in claim 1, wherein a conductive mesh film having a black treated layer, an optical film and an antireflection film are sequentially laminated on the front side of the transparent glass substrate.

4. The front filter for a plasma display panel as set forth in claim 1, wherein a conductive mesh film having a black treated layer, and a composite film having dual functions of optical and antireflection activities are sequentially laminated on the front side of the transparent glass substrate.

5. The front filter for a plasma display panel as set forth in claim 1, wherein the functional films are in the form of a roll or a sheet.
